(19) United States
(12) Patent Application Publication
(10) Pub. No.: US 2025/0298934 A1
(43) Pub. Date: Sep. 25, 2025

(54) SYSTEMS AND METHODS FOR ASSEMBLY LINE FITNESS ANALYTICS

(71) Applicant: Ford Global Technologies, LLC, Dearborn, MI (US)

(72) Inventors: Omar Makke, Lyon Township, MI (US); Oleg Yurievitch Gusikhin, Commerce Township, MI (US)

(73) Assignee: Ford Global Technologies, LLC, Dearborn, MI (US)

(21) Appl. No.: 18/611,198

(22) Filed: Mar. 20, 2024

(51) Int. Cl. G06F 30/20

(52) U.S. Cl. CPC G06F 30/20

(57) ABSTRACT

A system and method include acquiring data relating to an operation of an assembly line and generating a virtual environment of the assembly line using the acquired data. The virtual environment is defined using an assembly process model synchronized with real-time assembly line data. A task of one or more line workers is simulated using the real-time assembly line data, historical data, and sensor data. The assembly line is rebalanced in real-time based on the simulation to reduce a walk-time of the one or more line workers to perform the task.

### FIELD

The present disclosure relates to monitoring systems. More specifically, the present disclosure relates to systems and methods for operating a monitoring system incorporating a digital twin.

### BACKGROUND

The statements in this section merely provide background information related to the present disclosure and may not constitute prior art.

Manufacturing processes may be supervised with vision-based systems to monitor the processes. The monitoring systems may be implemented by using various kinds of devices, systems, and procedures. Some monitoring systems include imaging devices such as video cameras and infrared cameras for various purposes, such as to monitor production performance. Digitization of the processes, such as of an assembly line, can also be used as part of the monitoring. However, digitization of an assembly line can be challenging to perform because up-to-date information can be difficult to obtain without interfering with the operations along the assembly line, such as workers working at different workstations along the assembly line. Real-time monitoring can also be difficult to perform because such monitoring combines data sources from different operational databases having large amounts of data to be filtered.

The present disclosure addresses these and other issues related to monitoring production processes using digitization systems.

### SUMMARY

This section provides a general summary of the disclosure and is not a comprehensive disclosure of its full scope or all of its features.

The present disclosure provides a computerized method comprising: acquiring data relating to an operation of an assembly line; generating a virtual environment of the assembly line using the acquired data, wherein the virtual environment is defined using an assembly process model synchronized with real-time assembly line data; simulating a task of one or more line workers using the real-time assembly line data, historical data, and sensor data; and rebalancing the assembly line in real-time based on the simulation to reduce a walk-time of the one or more line workers to perform the task; wherein simulating the data comprises approximating the walk-time for a group of tasks using data acquired from one or more sensors along the assembly line; wherein the one or more sensors comprises an imaging device including a camera, a laser sensor, or an infrared sensor; wherein the virtual environment comprises a digital twin and the acquired data comprises data from one or more databases describing an assembly process of the assembly line, a vehicle to be assembled along the assembly line, a line layout for the assembly line, part locations, or a combination thereof; wherein the one or more databases comprises a line layout database, an assembly process database, a parts database, a plant IoT database, a vehicle CAD database, and a manufacturing CAD library database; wherein the assembly process model is synchronized with the real-time assembly line data using IoT messages; wherein the assembly line comprises a plurality of cells and the simulation comprises simulating different cell layouts for one or more cells of the plurality of cells and performing a sensitivity analysis to identify a cell layout optimization corresponding to a minimized walk-time; further comprising using an optimization algorithm to rebalance the assembly line, wherein at least a portion of the assembly line is rebalanced using one or more precedence constraints for a new part to be assembled along the assembly line or a new position of one or more items within the one or more cells; further comprising displaying the virtual environment of the assembly line with a plurality of cells including a plurality of items represented as a plurality of boxes within the plurality of cells and a plurality of walk patterns represented by a plurality of lines, and in response to receiving a user input virtually moving one or more of the boxes, updating the one or more walk patterns including moving one or more lines of the plurality of lines showing updated walk patterns; and further comprising using one or more APIs to cause the virtual environment to access one or more optimization functions to visualize an optimal solution for the one or more updated walk patterns corresponding to one or more different vehicle mixes along the assembly line.

The present disclosure provides a system comprising: a plurality of sensors configured to acquire movement data relating to movement of workers at an assembly line; and an analytics system receiving the movement data and configured to: acquire operational data relating to the operation of an assembly line; generate a virtual environment of the assembly line using the acquired movement data and the operational data, wherein the virtual environment is defined using an assembly process model synchronized with real-time assembly line data; simulate a task of one or more line workers using the real-time assembly line data, historical data, and the acquired movement data; and rebalance the assembly line in real-time based on the simulation to reduce a walk-time of the one or more line workers to perform the task; wherein the analytics system is further configured to simulate the data by approximating the walk-time for a group of tasks using the acquired movement data; wherein the plurality of sensors comprises an imaging device including a camera, a laser sensor, or an infrared sensor; wherein the virtual environment comprises a digital twin and the acquired data comprises data from one or more databases describing an assembly process of the assembly line, a vehicle to be assembled along the assembly line, a line layout for the assembly line, part locations, or a combination thereof; wherein the one or more databases comprises a line layout database, an assembly process database, a parts database, a plant IoT database, a vehicle CAD database, and a manufacturing CAD library database; wherein the assembly process model is synchronized with the real-time assembly line data using IoT messages; wherein the assembly line comprises a plurality of cells and the analytics system is further configured to simulate different cell layouts for one or more cells of the plurality of cells, perform a sensitivity analysis to identify a cell layout optimization corresponding to a minimized walk-time and display the virtual environment of the assembly line with the plurality of cells including a plurality of items represented as a plurality of boxes within the plurality of cells and a plurality of walk patterns represented by a plurality of lines, and in response to receiving a user input virtually moving one or more of the boxes, update the one or more walk patterns including moving one or more lines of the plurality of lines showing updated walk patterns; wherein the analytics system is further configured to use one or more APIs to cause the virtual environment to access one or more optimization functions to visualize an optimal solution for the one or more updated walk patterns corresponding to one or more different vehicle mixes along the assembly line; and wherein the assembly line comprises a plurality of cells, wherein the analytics system is further configured to use an optimization algorithm to rebalance the assembly line, and wherein at least a portion of the assembly line is rebalanced using one or more precedence constraints for a new part to be assembled along the assembly line or a new position of one or more items within one or more cells of the plurality of cells.

The present disclosure provides one or more non-transitory computer-readable media storing processor-executable instructions that, when executed by at least one processor, cause the at least one processor to: acquire data relating to an operation of an assembly line; generate a virtual environment of the assembly line using the acquired data, wherein the virtual environment is defined using an assembly process model synchronized with real-time assembly line data; simulate a task of one or more line workers using the real-time assembly line data, historical data, and sensor data; and rebalance the assembly line in real-time based on the simulation to reduce a walk-time of the one or more line workers to perform the task.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 illustrates an overall system for monitoring a production process in accordance with various implementations;

FIG. 2 illustrates a system for digital twin assembly line fitness analytics in accordance with various implementations;

FIG. 3 illustrates a representation of different lines of an assembly line using a chart in accordance with various implementations;

FIG. 4 illustrates a virtual representation of a cell showing walk patterns in accordance with various implementations;

FIG. 5 illustrates a precedence graph in accordance with various implementations;

FIG. 6 is an example of historical build sequences of parts in accordance with various implementations;

FIG. 7 illustrates a precedence graph generated in accordance with various implementations based on the historical build sequences of parts in FIG. 6;

FIG. 8 illustrates a user interface in accordance with various implementations;

FIG. 9 illustrates another user interface in accordance with various implementations;

FIG. 10 illustrates a simulation in accordance with various implementations; and

FIG. 11 is a flowchart illustrating an example method for performing assembly line fitness analysis using a digital twin in accordance with various implementations.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

The present disclosure provides a means for monitoring of a production process, such as an automotive process, using digitization (e.g., a digital twin) in various examples. For example, the digital twin of an automotive final assembly in various examples connects products, parts, tools, processes, and/or people that allows for monitoring production performance and enables assembly line fitness analytics (ALFA) that quantifies an effect of decisions in real-time and that allows for identifying opportunities for assembly line optimization. In some examples, digitization in combination with real-time monitoring and optimization allows for decision making that optimizes operations at one or more workstations along the assembly line, such as at the final assembly workstations. The decision making in some examples allows for more efficient and productive assembly line planning.

One or more implementations described herein can reduce or eliminate the challenging and complex process of assembly line monitoring, such as final assembly line monitoring with respect to digitization, real time monitoring and optimization, and decision making. For example, various implementations reduce or eliminate digitization challenges of a digital twin that needs up-to-date information for parts and tools positions, workers walk patterns, and access to operational databases securely, while respecting workers privacy and without interfering with the operations (e.g., allows for quickly querying an operational database for large data sets). Various implementations reduce or eliminate real-time monitoring challenges of combining several data sources from different operational databases, and efficiently displaying the most relevant information to the users. For example, the monitoring focuses on relevant information without having to apply filters or navigate complex user interfaces, such as when users are on the floor, holding a tablet while walking around, or a supervisor monitoring an entire assembly line (also referred to as a line).

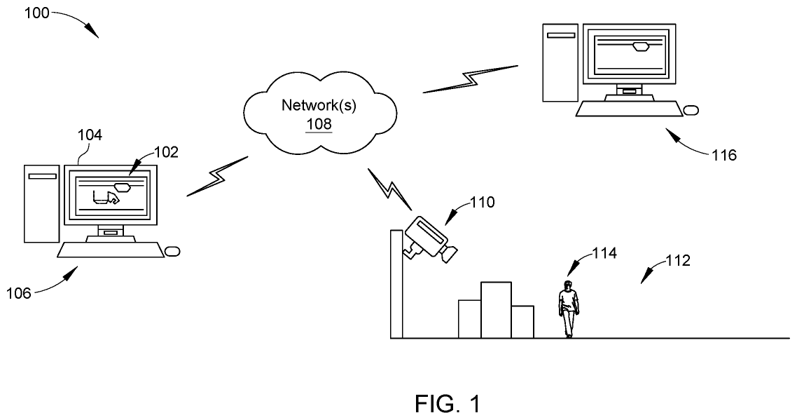

Some examples provide a digital twin implementation configured to perform Assembly Line Fitness and Analytics (ALFA). For example, ALFA is provided in connection with automotive assembly line planning, wherein one or more implementations include the digital twin that drives ALFA. One example, as illustrated in FIG. 1, shows a schematic block diagram illustration of a monitoring system 100, such as for monitoring a final assembly line process. Final assembly lines typically have a logical hierarchy provided as follows: A plant (or independent sections of a plant) contains lines. A line or group of lines focus on a specific domain, such as chassis or body assembly. Each line consists of cells, also known as workstations, which can be logical or physical in nature. Operators (or workers) are assigned to specific cells. Operations (or work instructions, work elements) are assigned to the workers in the cells. As should be appreciated, there is a balance between the line speed, complexity of operations, number of assigned tasks to the operators, and running the line smoothly without stoppages, among other factors. An operator taking more time than expected to execute an operation can cause a temporary line stoppage either immediately, or later when enough “extra time” has been consumed while executing that operation.

It is desirable to have the line run as fast as possible with the least amount of cells and without causing any manufacturing or assembly issues, all while adhering to the plant's requirements for ergonomics, proper operation, etc. Some examples use the minoring system 100 to perform line balancing optimization operations to one or more assembly lines. And, in some examples, cell layout optimization is performed to organize the layout of a cell to minimize non-value added steps, such as walking time. In combination with the line balancing and/or cell layout optimization, real-time monitoring of the line(s) identify potential issues and opportunities for optimization.

As can be seen in FIG. 1, the monitoring system includes a digital twin 102 that can be displayed on a screen 104 of a computing device 106, such as a computer or other processing machine. The computing device 106 may be coupled via a network 108 to one or more sensors 110, such as an imaging device 100 that is configured to capture one or more images or other sensor data of one or more cells 112 (e.g., final assembly workstations). For example, the one or more sensors 110 in some implementations are configured to acquire sensor data relating one or more workers 114 (e.g., operators) that allows for approximating the walk-time for a group of tasks for the one or more workers 114 as described in more detail herein and that can be used, for example, to rebalance one or more lines. It should be appreciated that one or more sensors 110 can be any type of sensor capturing different types of sensed data in any type of surveilled area, such as along an assembly line or portions thereof.

The network 108 may include any one or a combination of various networks such as a data network, a telephone network, a cellular network, a cable network, a wireless network, a private network, a public network, a local area network (LAN), a wide area network (WAN), and the Internet. In some instances, the network 108 may support communication technologies such as Bluetooth, cellular, near-field communication (NFC), Wi-Fi, and/or Wi-Fi direct. In some examples, the computing device 106 may be directly coupled to the one or more sensors 110 via an electrical cable or a fiber optic cable and communicatively coupled via the network 108 to other components such as a server system 116.

The one or more sensors 110 can include various types of imaging devices such as, for example, a digital camera configured to take snapshots of the one or more cells 112 (e.g., on a periodic basis, an intermittent basis, or as-needed basis), a video camera configured to generate video files based on video surveillance of the one or more cells 112, and/or an infrared camera configured to generate infrared imagery (snapshots and/or video) of the one or more cells 112, among others. The one or more sensors 110 may also include other components or sensing devices, such as a motion detector or a speed sensor. The motion detector may be used in some applications to trigger image capture (or video capture) in the one or more sensors 110. The speed detector may be used to obtain motion information associated with one or more moving objects in the one or more cells 112, such as a walking speed of the one or more workers 114. In some implementations, the motion information may be a numerical speed value of a moving object in the one or more cells 112. The numerical speed value may be transmitted to the computing device 106 or the server system 116 via the network 108. The numerical speed value may further include a time-stamp that is indicative of a time at which the speed of the moving object was captured. In some implementations, the computing device 106 may determine a speed of an object by processing multiple snapshots or video frames captured by the one or more sensors 110 and transmitted to the computing device 106 or the server system 116 (e.g., walking speed, step speed, number of steps, etc.).

It should be noted that the one or more cells 112 can include different surveilled areas, for example, along an assembly line. The one or more cells 112 can contain parts and equipment useful for assembling different vehicle types, such as a vehicle with an internal combustion engine (ICE) and a hybrid vehicle. However, the surveilled areas, such as the one or more cells 112 may be any of various other types of areas placed under surveillance, such as different workstations along one or more assembly lines that are used to assemble one or more different types of vehicles. Each of these areas may include a combination of moving objects (e.g., vehicles being assembled and workers 114) and stationary objects (e.g., equipment, parts, tools, storage containers, machinery, packages, poles, racks, etc.) over one or more periods of time. Thus, when the surveilled area includes one or more cells 112 that are on a factory floor for assembling vehicles, the moving objects and the stationary objects are any object that are included in the assembly process in some examples.

In some examples, when two different vehicle types move down the assembly line, each vehicle can have different unique operations to be performed in connection with the assembly of each vehicle. For example, consider a case where vehicle A is an ICE engine with a turbo charger, while vehicle B is a hybrid vehicle. Each vehicle type can have some unique operations and some common operations may require different times to finish (e.g., a battery is partially blocking installation on HEV vehicles). Let to be the tact time which specifies a global maximum time a vehicle is worked on in each cell 112. Let tⁱ_{w} be the average amount of time the worker 114 in the cell 112 i spends time working and not waiting for a new vehicle. Given N cells in a line, let T={Tⁱ_{w}: 1<=i<=N}. Let t_{wavg} be the average of the elements of T. Assuming that t_{w}∈T=⇒t_{w}≤t_{c} to prevent overworked cells 112 skewing the average, then the line utilization rate can be defined as:

$$u = \frac{{tw}_{avg}}{{t}_{c}} \qquad Equation ( 1 )$$

A balanced line means that each worker 114 in the cells 112 works the same amount of time. In other words, if d=sup T−inf T, then ideally d=0. An efficient line can then be defined to be a balanced line with a utilization factor larger than a defined quantity. Note that u<=1 since tw_{avg}≤t_{c}. As such, various examples perform line balancing to minimize d and 1−u as described in more detail herein.

The sensor data, for example, images captured by the one or more sensors 110 may be received by the computing device 106, processed for obtaining information about the one or more cells 112, and used for generating the digital twin 102 that is displayed on the screen 104. In at least some implementations where the one or more sensors 110 is configured to transmit real-time images of the surveilled area(s) within the one or more cells 112, the digital twin 102 may be updated in real-time for rendering a real-time digital replication of the one or more cells 112 and used for ALFA as described in more detail herein. When rendered in real-time, any changes in the surveilled area(s), such as for example, workers 114 or vehicles moving in and out of the surveilled area(s) can be detected by the computing device 106 and used for various purposes, including one or more processes or operations as described herein.

In one exemplary application, the computing device 106 may be configured to generate a virtual environment of the assembly line using acquired data, wherein the virtual environment is defined using an assembly process model synchronized with real-time assembly line data as described in more detail herein. The computing device 106 further may be configured to simulate a task of one or more of the workers 114 (e.g., line workers) using the real-time assembly line data, historical data, and sensor data from the one or more sensors 110 to allow for rebalancing the assembly line in real-time based on the simulation to reduce a walk-time of the one or more workers 114 to perform one or more tasks. It should be noted that the computing device 106 is operable in combination with the server system 116 to perform one or more processes or operations as described herein. For example, the server system 116 can be a cloud-based system that includes one or more computing device containing components such as processors and memory devices. In the illustrative example shown in FIG. 1, the server system 116 can include at least one computer having at least a processor and a memory. The memory, which is an example of a non-transitory computer-readable medium, may be used to store various types of information such as real-time assembly line data, historical data, and sensor data. The server system 116 may respond to a request received from a computer such as the computing device 106, by transmitting the requested information via the network 108.

The information received from the server system 116 may be used by the computing device 106 to process sensor data (e.g., images) and other data received from the one or more sensors 110 and operate the digital twin 104 in accordance with one or more embodiments of the disclosure. The methods for processing sensor data and/or operating the digital twin 104 may provide various advantages such as optimizing the balancing of assembly lines to operate in various environments and various applications, and assembling vehicles of different types along the assembly line, using digitization and real-time monitoring as described in more detail herein. It should be noted that the various components described herein can cooperate to acquire data and generate desired information about surveilled areas.

For example, one or more implementations allow for optimizing the layout of a workstation to facilitate balancing assembly line operations. In particular, the efficiency of the line u described above is defined across the entire line. It should be appreciated that “busy” does not mean “value added” in various examples. For example, “non-value” added time is due to walking back and forth from the installation points on the vehicle to the racks to grab parts, and to the tools, garbage bins, etc. Some of these walk patterns are needed but can be minimized by optimizing the location of the racks, garbage bins, and parts in the cells using one or more embodiments. For example, let tₜₒₜₐₗ be the amount of time the worker 114 spends not waiting for a vehicle to arrive. Let t_{valueAdded} be the time spent installing parts in a vehicle (excluding walking, breaking boxes, moving items, preparing the tools, etc.). The efficiency of a cell 112 (e_{c}) can then be defined as:

$${e}_{c} = \frac{{t}_{valueAdded}}{{t}_{total}} \qquad Equation ( 2 )$$

Thus, in some examples, workstation layout optimization in the one or more cells 112 is performed to identify a suitable layout for the items in a workstation that maximizes e_{c}, while adhering to design constraints, such as imposed by different requirements. For example, with major and minor model changes, different parts may be used and operation times within the one or more cells 112 based on cell layout can change. In one or more examples, the positioning of items within the one or more cells 112 and travel paths of the workers 114 can be changed in response to changes in vehicle models or other operational changes to rebalance the lines, which can occur in real-time (e.g., by simulating tasks using the digital twin 104).

As an example, if the order of the vehicle types changes, the corresponding operating times will change. For example, determining the vehicle sequence for (HEV, HEV, Gas) can be more complex than the vehicle sequence for (HEV, Gas, HEV). This is because the HEV type may cause the operator 114 to work more than to, but the operator 114 can recover the lost time while working on a gas vehicle type. The input also uses multiple heterogeneous data sources, such as CAD layout, IoT messages, and relational databases and there are additional constraints to consider, such as tool constraints, constraints from “lessons learned”, ergonomics, operator skill, lighting and visibility, etc. Additionally, using up to date information by retrieving the information in real-time (e.g., if the industrial engineer moves a rack on the floor to a different position), one or more examples allow for a corresponding update of the digital twin 104. That is, in various examples, the digital twin 104 is more efficiently updated to allow for more efficient assembly line operation (e.g., more efficient rebalancing and cell layout).

In some examples, the digital twin 104 provides an efficient and effective approach when performing line balancing and cell layout to facilitate other assembly line fitness analytics tasks. Fitness analytics in some examples is the measurement of the efficiencies for the different manufacturing domains in near real-time, predicting future scenarios and issues, and identifying possible methods to resolve the identified issues. In one example, an assembly line fitness analytics system has the following properties:

1. Descriptive: Fully represents the floor operations and allows users to “slice and dice” the data for quick insights. Combines data from various manufacturing systems for real-time analytics to assist in modifying the assembly work instructions to increase the efficiency of the line.

2. Predictive: Highlights existing issues before occurrence and predict future issues. View the effects of decisions to be taken.

3. Prescriptive: Optimizes cell layouts and line layouts and allows the creation of “what-if” scenarios. Automatically generates sequencing constraints by taking the users decisions into account.

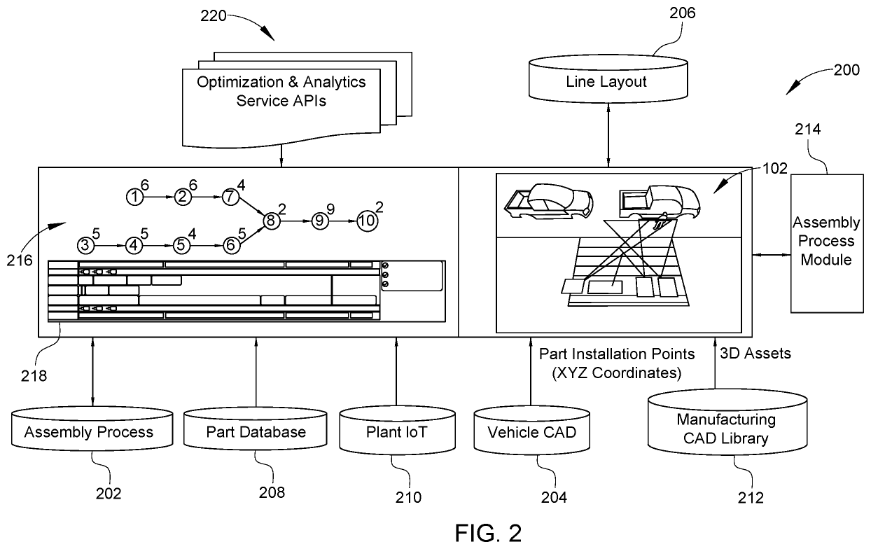

An example of a system 200 for digital twin ALFA is shown in FIG. 2. The illustrated system 200 integrates multiple data sources (e.g., heterogeneous data sources or databases), such as data from an assembly process database 202, a vehicle CAD database 204, a line layout database 206, a parts database 208 (e.g., a parts location database), a plant IoT database 210, and a manufacturing CAD library database 212 to generate an assembly process model 214, while synchronizing the assembly process model 214 with the actual assembly line through IoT messaging. As such, near real-time visibility is provided into the assembly line operations. The system 200 in some examples integrates historical data, present data, as well as real time IoT messages to identify opportunities to increase efficiency as described in more detail herein.

In some examples, the assembly processes described herein relates to the steps performed at each cell 112 (e.g., different tasks) to assemble the vehicles in various examples. The steps in various examples are assigned MODular Arrangement of Predetermined Time Standard (MODAPTS) codes. Each step, whenever applicable, is associated with parts and/or tools. As an example, the step “Destroy and throw box when its empty” does not have any parts associated with this step. The details for these parts and tools such as size, description, which vehicle configuration the parts/tools apply to, etc. are obtained from the parts database 208. Each step has an associated time obtained through MODAPTS time estimation or through an actual time study on the floor. The plant IoT database 210 provides information, such as regarding the actual sequence of vehicle types moving across the floor, messages indicating which parts have been scanned, messages showing which cell 112 caused the line to stop and for what reason (e.g., missed scan, manual stop, etc.), and in some cases messages showing which racks have been refilled with parts. The vehicle CAD database 204 contains data relating to the installation points for the parts in the vehicle. Since this is a single point, the point is usually the center of mass of the part, and therefore is also an approximation in various examples. This vehicle CAD database 204 also includes information such as part weight, and in some cases for large parts, a three-dimensional (3D) representation of the part which can be integrated in 3D environments. The manufacturing CAD library database 212 contains 3D representations for the tools, racks, bins, etc.

In one or more examples, an application programming interface (API) layer allows various optimization algorithms and services to be integrated within the digital twin 104. For example, ergonomics rules can change often based on new parts. Some rules, when updated, have to be implemented quickly. Furthermore, there can be special business rules such as: “If two different parts fit the same tool, they must be in different cells”. Such rules and constraint checks which typically respond with YES/NO are suitable for implementation as an API layer having one or more APIs 220 (e.g., optimization and analytics service APIs) in some examples. This is because different plants may have slightly different rules, and these rules are managed outside the digital twin 104 in one or more examples. The API layer also allows the digital twin 102 to synchronize virtual objects with the real world, such as worker 114 location and location of parts, racks and bins in every cell 112.

It can be difficult to maintain up-to-date layout information of the cell 112 because industrial engineers may find a good optimal solution while on the line, when observing a specific issue. Therefore, one or more examples includes a vision system (e.g., the one or more sensors 110 providing vision data) that monitors each cell 112 and extracts the layout information. Further, this vision system can monitor when workers 114 enter and leave the cell 112. This information is useful in the calculations of the walk pattern analysis as described in more detail herein. For example, the time it takes for the worker 114 (e.g., an operator) to walk to the vehicle and execute a set of operations and come back can be accurately calculated. The digital twin 102 in some examples integrates digital versions of lean manufacturing tools, such as a virtual white board 216, a chart such as a Yamazumi board 218, etc., and allows different users to interact with these tools, which in some examples is simultaneously. The digital twin 102 also provides simulations or predictions in some examples.

A virtual change can be made within the digital twin 102 to see how the system changes before making any changes to the original system. To achieve this, vision-based and sensor-based synchronizations are used to maintain some of the information required by the digital twin 102, such as rack location identification, vehicle location identification, worker location identification (either visually or by synchronizing scanning messages), etc. In the absence of this information, one or more examples utilize estimation algorithms to approximate the unknown states. For example, if the line speed is known, the location of the vehicle on the line is obtained from the sensor 110, and a vision based trigger only indicating when the worker 114 has entered or left the cell 112, one or more implementations estimate the operator's location outside the cell 112 when working on the vehicle, and then corrects the “history” when the worker 114 walks back into the cell 112. This type of estimation in some examples is performed as a service and integrated via the APIs 220 to simplify the digital twin 102 in some examples. Thus, coordaining and combining all this information allows for considering optimization for the line and the cell layout.

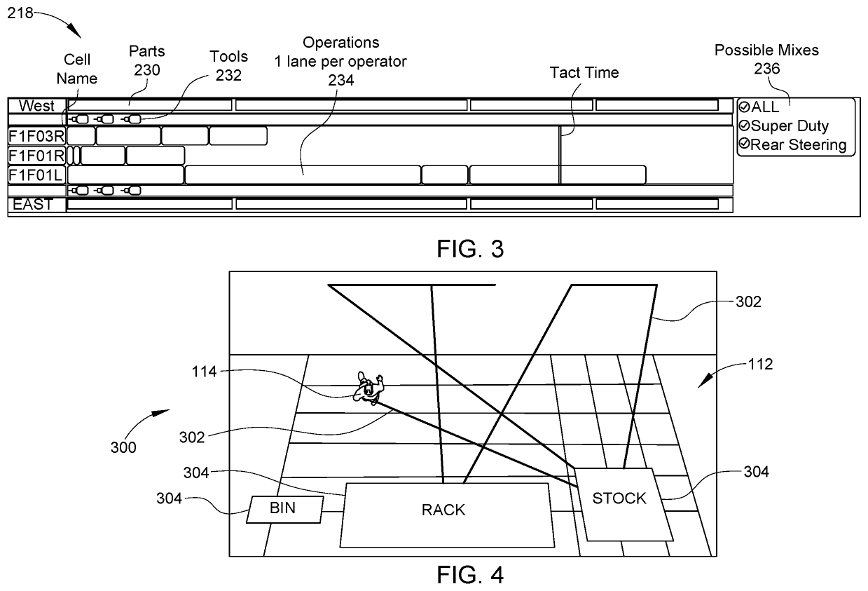

In some examples, a processing engine (e.g., a game engine) is used to visualize the assembly process and provides interactive tools to support human decision makers. Visualization views are built for 3D cell layout representation, 3D line representation, as well as 2D digital versions of lean manufacturing tools as shown in FIGS. 3 and 4. For example, FIG. 3 illustrates an updated Yamazumi Board 218 that shows parts 230, tools 232, operations 234, and different mixes 236, among other data, on the line. FIG. 4. Illustrates a digital virtualization 300 of a virtual environment generated in accordance with an embodiment. The digital virtualization 300 shows walk patterns 302 for the worker 114 in the cell 112, wherein walk pattern analysis and cell layout optimization can be performed in isolation from the rest of the line in various examples. In some examples, the digital virtualization 300 is a representation of the digital twin 102 (that can be generated in some other examples with CAD tools) that is compiled on various different platforms such as MAC, PC, Android tables, Apple tablets, etc. with virtual and augmented reality integrated therein with support for multiple drivers and GPU features. In some examples, “multiplayer” style (and “free-style” approach) interactivity of the digital virtualization 300 is provided when multiple users are optimizing the line simultaneously, with the networking synchronization performed by the processing engine. It should be noted that any tacked bar chart that shows the source of the cycle time in a process that graphically represent processes can be used.

In various examples, the digital twin 102 is configured to provide insights, visualization, simulation, analysis, and/or prediction while supporting multiple entities (e.g., industrial engineers running the line, line supervisors, engineers working on new line, etc.). In some examples, a user interface (UI) is provided having separate and dedicated views for performing different tasks relating to line balancing, cell layout optimization, etc. instead of one UI. However, a single UI can be provided in some examples.

In various examples, cell layout and worker (e.g., operator) walk pattern analysis is performed. For example, the cell layout optimization is performed to minimize the duration of non-value added tasks by reducing walk times. This will result in either faster line speed or reduced number of cells in some examples. The walk patterns 302 in one example are shown in FIG. 4, and as the boxes 304 (e.g., digital box representations of bins, racks, parts (stock), etc.) are moved (e.g., virtually dragged) around the cell 112, with the walk patterns 302 updated while the boxes 304 are moving. In some examples, the system 200 interacts with the data and conducts sensitivity analysis as described in more detail herein to generate updated walk patterns 302 for display. For example, the operations illustrated in the Yamazumi Board 218 shown in FIG. 3 can be imported into the cell 112, which then allows the user to analyze how different variants of the cell layout affect the worker performance. A sequence of different vehicle mixes can be provided to analyze the walk patterns 302 for that specific sequence. In operation, using the APIs 220, the digital twin 102 can call optimization functions and visualize the proposed optimal solution and, if necessary, manually adjust the proposed solution as described in more detail herein. It should be noted that analysis becomes more complex if more than one worker 114 is working in the cell 112 (e.g., it can be difficult to calculate the actual walk paths due to the possibility of interference). In this case, the processing engine uses path finding capabilities to assist in the simulation. For example, each agent in the simulation can have a corresponding script implementing associated behavioral logic, and when the simulation runs, the actual walk paths can be obtained based on how the agents interact.

In some examples, monitoring activities on the assembly line are combined with the optimization. As discussed herein, the digital twin 102 in one or more examples calls the APIs 220 (e.g., vision system APIs 220) to obtain information when the workers 114 have left and entered the cell 112, and where the worker 112 walked to within the cell 112. The digital twin 102 is configured to trace the actual visible walk path. In some examples, the remainder of the path is estimated, such as by using the IoT messages for scans, tools actuation, and vehicle location on the line as described herein. Then it is possible to go back in time to understand why the line stopped. The digital twin 102 in some examples aggregates the data relating to line stoppages and highlights “hot zones” on portions of FIGS. 3 and 4.

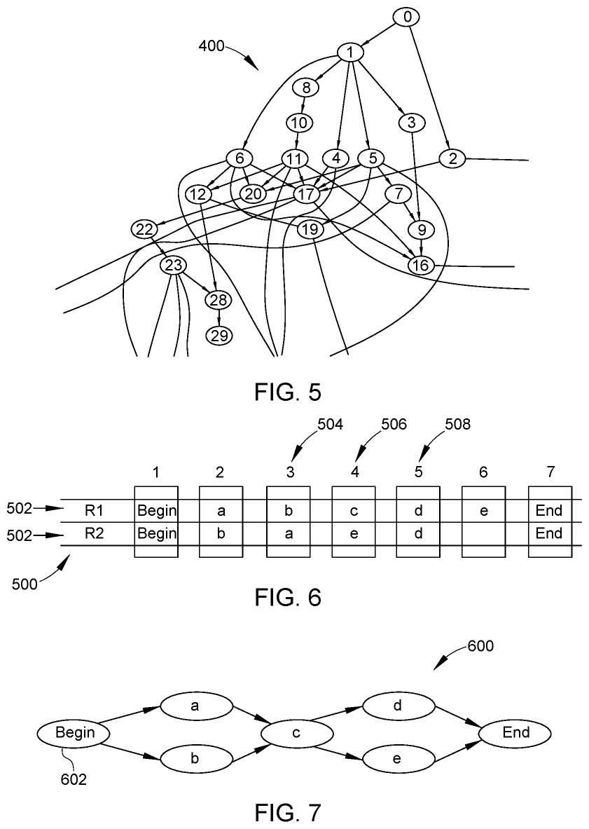

The digital twin 102 in some examples also allows analysis of “what if” scenarios. For example, line optimization which extends beyond cell layout needs the knowledge of the precedence constraints for the vehicles being built. These precedence constraints can be captured in some examples in a form of a directed acyclic graph (DAG), also referred to as a precedence constraints graph 400, a portion of which is shown in FIG. 5 with one or more rules. For example, the rules include that the root of the precedence constraints graph 400 is a Begin node, which can be artificially added to identify the start of the precedence constraints graph 400. Each and every node on the precedence constraints graph 400 has a path to an End node, which can be artificially added at the end of the precedence constraints graph 400. Additionally, the precedence constraints graph 400 has the following No Shortcuts property: For any two nodes A, B on the DAG, if a node A directly precedes node B, i.e., there is an arrow connecting A directly to B, then there is no other path from A to B other than this direct connection. That is, this direction connection is not a shortcut for a longer path.

In some examples, the precedence constraints graph 400 is used as follows: For any arbitrary node n on the precedence constraints graph 400, all the previous nodes which have a path to n must be installed. It should be appreciated that there can be a maximal graph, a minimal graph, and a target graph which is located in between, and provides an algorithm to mine the graph. In some examples, consideration is also given to the nodes on the precedence constraints graph 400 being parts. For example, parts between model years can change, and parts for the same model year and vehicle type can change depending on the selected build options and trim level (e.g., HEV, etc.). This implies that some parts are not always present on the precedence constraints graph 400, and hence for each specific build, the nodes on the precedence constraints graph 400 which do not apply are shorted out (connects the previous nodes to its following nodes) in some examples.

In the illustrated example of FIG. 5, the nodes correspond to part IDs and an order of installation. In this example, the part having part ID=0 must be installed first. Then, either part with part ID=1 or part ID=2 may be installed. Using various implementations described herein and applied to part ID 10, in order to install the part corresponding or associated with part ID 10, part ID 8 must be installed, and before part ID 8 is installed, part ID 1 must be installed. As another example and considering part ID 20, before installing this part, part ID 6, part ID 11, and part ID 5 must be installed. As such, the nodes define the following installation sequence:
Before installing part ID 11, part ID 10 must be installed,
   Before part ID 10, part ID 8
      Before part ID 8, part ID 1
         Before part ID 1, part ID 0
Before installing part ID 6, part ID 1 must be installed,
   Before part ID 1, part ID 0 must be installed.
Before installing part ID 5, part ID 1 must be installed, and before part ID 1, part ID 0 must be installed.

Thus, as should be appreciated, each node on the graph 400 must be installed before the nodes that follow. That is, a part cannot be installed until the parts preceding that part are installed. The graph 400 is representative of the order of the installation using parts corresponding to the part IDs for the various nodes and is used in one or more examples as described in more detail herein. It should be noted that if a part is not needed (e.g., an optional part) for a vehicle, the node is “shorted out”, such that the output of the node connects to the input nodes.

In some examples, the interpretation of historical data can vary between domains. For example, if a log file L has the following entries: L₁: {A, B, C, D}, L₂: {A, B, D}, and L₃: {A, B, C}, the following decision is to be made: either choose that “Whenever C and D appear, C must precede D”, or “C and D are independent of each other”. In these examples, a heuristic algorithm is used that is generated using set theory, to account for “optional” parts. The algorithm constructs the precedence constraints graph 400 while scanning the historical data. Therefore, if the logs are sorted so that newer information is first, newer information will be prioritized in constructing the precedence constraints graph 400. FIG. 5 shows a section of the generated precedence constraints graph 400. The precedence constraints graph 400 represents a large number of parts, and is used by one or more processing engines in various examples as the precedence constraints graph 400 is complex to understand visually. That is, in some examples, the precedence constraints graph 400 cannot be understood visually.

The algorithm in some examples uses as an input a historical build sequences of parts 500 as shown in FIG. 6, where each row 502 represents a historically valid sequence. The algorithm in various examples processes the data in the historical build sequences of parts 500 column by column, starting from the top row 502 to the last row, and builds the precedence constraints graph 400 as the algorithm receives and processes the data (e.g., dynamically generates the precedence constraints graph 400). In some examples, older sequences are positioned lower than newer sequences. Each part number in a sequence appears only once. If the same part appears multiple times, a number can be appended to the end of the part number to make each one unique. Without loss of generality, assume the algorithm finished in the third column 504 (column 3), and hence, there already exists a partial precedence constraints graph 400, and now the algorithm is starting at column 506 (column 4). In one example, the algorithm performs the following:

1. Loop through all the r rows of the column 506 (column 4) (c then e). Each row represents a labeled node n⁴ᵢ where 1<=i<=r.

2. If node n⁴ᵢ is already in the graph, do nothing, go to step 1.

3. If there are no more rows 502, move to the next column 508.

4. If there are no more columns, write the precedence constraints graph 400 and terminate the algorithm.

5. For each n⁴ᵢ, find all the nodes in the table which have same label as n⁴ᵢ. In the case of node c, it is the only one. In the case of e, there are two e nodes in the table. Define I as: n∈I=⇒n has same label as n⁴ᵢ.

6. For each n∈I, grab all the ordered sequence of nodes Iᵢ where 1<=i<=r that precede it. For node c, this is {Begin,a,b} and for node e, this is {Begin, a, b, c, d} and {Begin, b, a}. Then, Lⁱ={Iᵢ}.

7. Then calculate

$${P}^{i} ⟵ \begin{matrix}Ω \\ li ∈ L\end{matrix} / i .$$

Connect all nodes in Pⁱ←i to n⁴ᵢ, scan the graph, and remove any shortcut. For node c, P c←={Begin,a,b} and for node e, P^{e}←=={Begin, a, b}.

8. Repeat steps 4 and 5, but looking forward instead of backwards. For node c, P^{c}→={d,e,End} and for node e, P^{e}→={End} and {End}. Connect c to {d,e,End} and remove shortcuts, connect e to {End} and remove shortcuts.

The output of the algorithm after processing the historical build sequences of parts 500 is shown in FIG. 7 as a graph 600. It should be noted the first step in various examples always adds a {Begin} node 602 to the graph 602. In general, the generated graph 600 can look different if the rows are sorted differently, such that newer information is prioritized. Also, a modification can be made to the algorithm in steps 4 and 5. For example, steps 4 and 5 can be summarized as: A node nⱼ precedes nᵢ if whenever nᵢ appears, nⱼ appears before it”. This condition can be changed to process “optional” parts differently. The condition is: “A node nⱼ precedes nᵢ, if, whenever nⱼ appears in a sequence, it is before nᵢ”. Let I_{←} be all the nodes that appear before a node nᵢ for all the rows. Let I_{→} be all the nodes that appear after the node nᵢ for all the rows. Then, for node nᵢ, it is preceded by P_{←}=I_{←}\I_{→}, and node nᵢ precedes P_{→}=I_{→}\I_{←}.

To generate the graph 600 (e.g., a precedence constraint graph) for automotive assembly, the sequence of part numbers is used while ignoring mounting part such as nuts and bolts, as the parts can be treated as one “super part” with the part that these parts support. In the illustrated example, five years of data is used (although other periods can be used), and considering multiple line rebalances occur during a year, each year provides multiple sequences to generate the graph 600. For new parts, in some examples, a domain expert manually inserts the part in a valid sequence and generates a log. After a few generations, optimization with the new part is performed with the algorithm. In some examples, with the precedence graph mined, as the user of the digital twin 102 drags and drops tasks on the Yamazumi board 218, the digital twin 102 shows the boundaries of where the item can be dropped. If constraints are generated for new parts, then the optimization algorithm can rebalance the line.

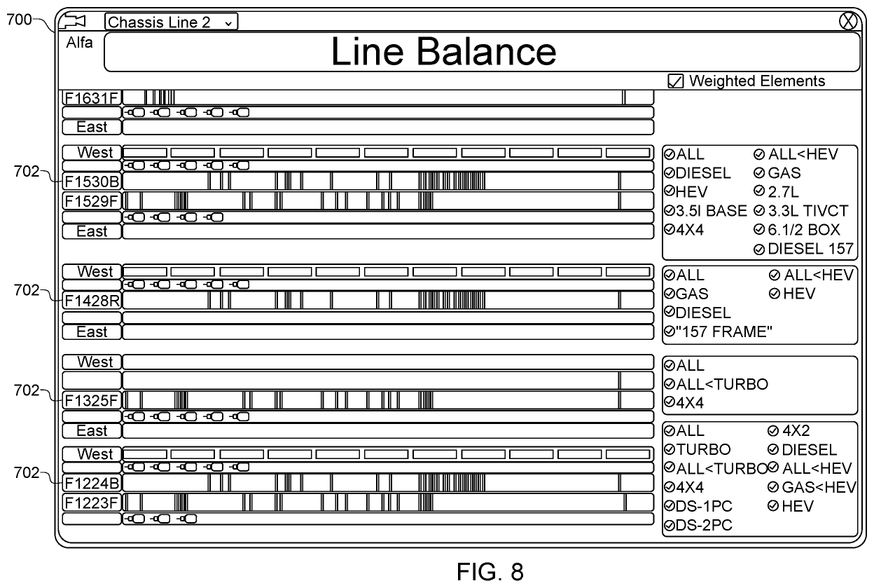

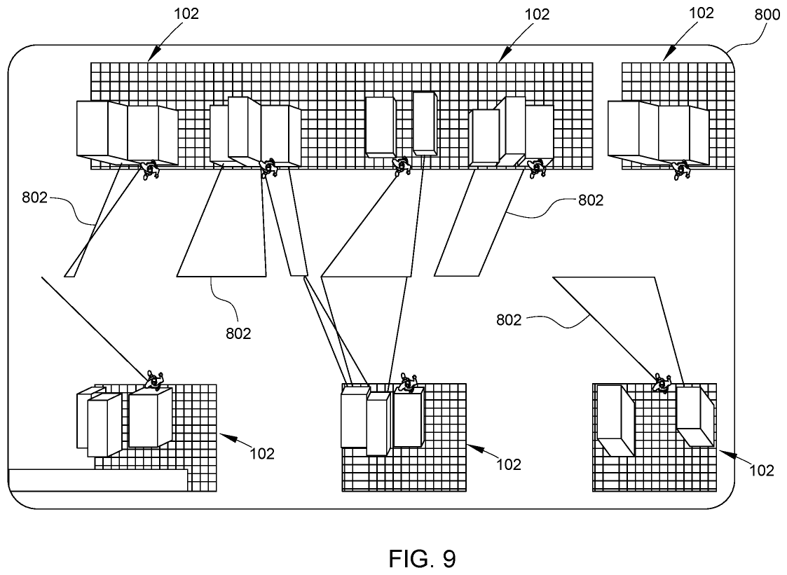

Thus, in various examples, the digital twin 102 is configured as a decision support tool in assembly line rebalancing. Once the precedence constraint graph 400, 600 is in generated, in some examples, the user can choose either to rebalance an entire line automatically, which can be difficult without knowing all other constraints on the line (e.g., light intensity, ergonomics, tools constraints, etc.) or select step by step the next optimizations steps to perform. In this case, based on the precedence constraint graph 400, 600, all the other factors not yet present in the digital twin 102 can be considered with the next optimization step not made until the line is balanced. In one example, line balancing is performed using the user interface 700 shown in FIG. 8 and the user interface 800 shown in FIG. 9. The user interfaces 700, 800 in some examples are displayed side-by-side to a user. However, different display configurations are contemplated. The user interface 700 displays the tasks on the line in each cell 112, along with the parts and tools present in each cell 112 and possible mixes (e.g., different combinations of parts). The information is implemented as a graph as described in more detail herein. When the user selects a task, the parts, tools, and build options are selected. If there is a similar tool or part in another cell 112, the tool or part also is highlighted. As such, the user can quickly determine the complexity of moving a task from one cell 112 to another cell 112. The user interface 800 shows walk patters 802 for every cell 112 based on a provided sequence of vehicles. The user can choose to view, for example, a cell layout view as shown in FIG. 4, or optimize the cell layout from the line view in the user interface 700. In some cases, a part needed by one cell 112 can be placed in another cell 112 if the operation is too long. Thus, the digital twin 102 allows balancing the line and the cell layout simultaneously with the user interfaces 700, 800. Changes made to the line by moving the horizontal bars 702 (representing work tasks) are reflected on the line, and the walk pattern lines 802 are modified. The digital twin 102 moves all the tools and parts needed for that task to the new cell 112.

In some examples, worker overload and interference are predicted. For example, predicting operator overload is approximated by performing the walk pattern analysis in every cell 112 individually. However, it should be appreciated that the analysis becomes more complex when there are two or more workers trying to install parts at the same time. Also, in some examples, the walk pattern analysis assumes the walks are completed in straight lines, and there are no roadblocks in between. The digital twin 102 in some examples facilitates predicting operator overload and interference by simulating an upcoming vehicle sequence using path finding. For example, some walk areas can be blocked and the simulated worker 114 will find a path to the destination that does not include the blocked path.

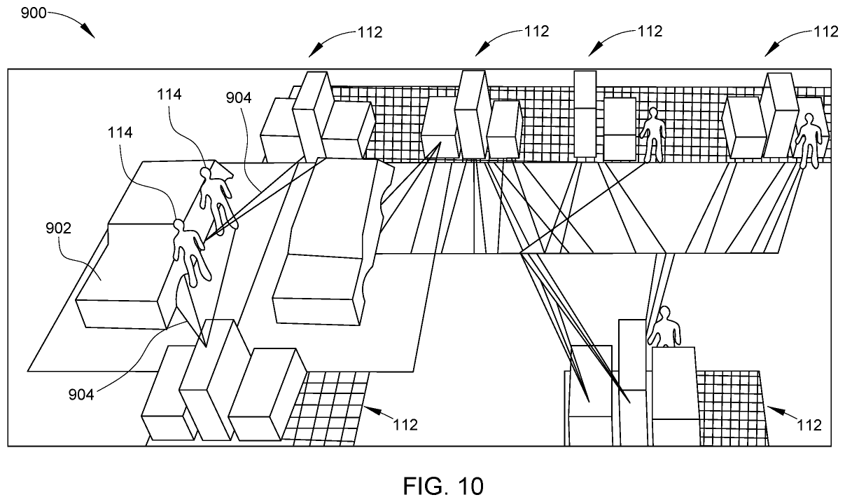

Additionally, worker contact detection can be performed in some examples. If two workers 114 get close enough to each other in some examples, the worker that is going to make contact will send a message about the objects that will be in contact, indicating interference. Running the full simulation, the user of the digital twin 102 can obtain a report about the number of interference occurrences, duration of the occurrences etc. In one example, during conditions that include contact events, all the installation times are increased by a factor determined by a domain expert. Then, the simulated walk patterns will deviate from the calculated walk patterns, but as the digital twin 102 runs the simulation, the simulated walk patterns are traced and the zones of interference highlighted in some examples. For example, as shown in the simulation 900 of FIG. 10, if the two workers 114 working on the gas vehicle 902 touch (e.g., make contact with each other) while moving along a path 904 during the simulation, contact between workers is identified and an alert can be provided.

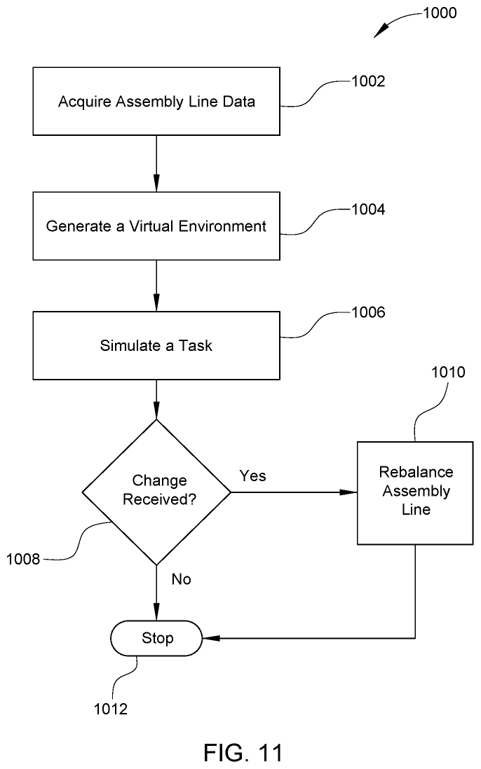

FIG. 11 is a flowchart illustrating an example method 1000 for performing assembly line fitness analysis using a digital twin in accordance with various implementations, such as may be performed by the system 200. At operation 1002, data relating to an operation of an assembly line is acquired. For example, as described in more detail herein, the one or more sensors 110 acquire data relating to movement of workers(s) 114 within one or more cells 112 along an assembly line.

At operation 1004, a virtual environment of the assembly line is generated using the acquired data. For example, the virtual environment is generated as the digital twin 102 and defined using the assembly process model 214 synchronized with real-time assembly line data determined from the acquired data (e.g., walking paths, walking times, etc.). The digital twin can use data acquired from one or more databases describing an assembly process of the assembly line, a vehicle to be assembled along the assembly line, a line layout for the assembly line, part locations, or a combination thereof.

At operation 1006, a task of one or more line workers is simulated using the real-time assembly line data, historical data, and sensor data as described in more detail herein. For example, an assembly operation performed by one or more workers 114 within the cell 112 is simulated (e.g., gathering a part from a bin, obtaining a tool to perform the operation, assembling the part to the vehicle, returning the tool to a cart, etc.). In some examples, the assembly line comprises the plurality of cells 112 and the simulation comprises simulating different cell layouts for one or more cells 112 of the plurality of cells 112 and performing a sensitivity analysis to identify a cell layout optimization corresponding to a minimized walk-time.

A determination is made at operation 1008 whether a change has been received. For example, is a simulation change made to the cell 112, such as to change a travel path of the worker 114, move one or more items in the cell 112, etc. As described herein, one or more user interfaces can be used to view and modify the simulation data and dynamically review the results (e.g., changes to tasks in a particular cell). For example, simulating the data includes approximating the walk-time for a group of tasks using data acquired from one or more sensors along the assembly line.

If a determination is made that a change has been made, in some examples, at operation 1010, the assembly line is rebalanced in real-time based on the simulation to reduce a walk-time of the one or more line workers 114 to perform the task. For example, line balancing changes and/or corresponding walk pattern lines are modified at operation 1010. In some examples, an optimization algorithm is used to rebalance the assembly line, wherein at least a portion of the assembly line is rebalanced using one or more precedence constraints for a new part to be assembled along the assembly line or a new position of one or more items within the one or more cells. In some examples, the virtual environment of the assembly line is displayed with a plurality of cells including a plurality of items represented as a plurality of boxes within the plurality of cells and a plurality of walk patterns represented by a plurality of lines, and in response to receiving a user input (at operation 1008) virtually moving one or more of the boxes, or one or more walk patterns including moving one or more lines of the plurality of lines are updated showing updated walk patterns, resulting in rebalancing of the assembly line at operation 1010 in some examples.

If no changes are received or after the assembly is rebalanced, the method 1000 stops at operation 1012.

Thus, one or more implementations described herein provide assembly line optimization using the digital twin 102. For example, using precedence constraint graphs generated by the herein described algorithm based on set theory, which generates the precedence graph while prioritizing newer information, different parts can be accommodated in the model (e.g., optional parts). Since the digital twin 102 can call on any optimization algorithm through the APIs 220, as the users work on the line and save their work, the digital twin 102 is able to identify further opportunities for optimization by calling these micro-services. Therefore, the fitness of the line is continually analyzed in some examples. By combining the interactivity and visualization of the digital twin 102 with fitness analytics results in the ALFA with enhanced performance that, for example, allows for integrating heterogeneous databases together with IoT messages.

Unless otherwise expressly indicated herein, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, material, manufacturing, and assembly tolerances, and testing capability.

As used herein, the phrase at least one of A, B, and C should be construed to mean a logical (A OR B OR C), using a non-exclusive logical OR, and should not be construed to mean “at least one of A, at least one of B, and at least one of C.”

In this application, the term “controller” and/or “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components that provide the described functionality; or a combination of some or all of the above, such as in a system-on-chip.

The term memory is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general-purpose computer to execute one or more particular functions embodied in computer programs. The functional blocks, flowchart components, and other elements described above serve as software specifications, which can be translated into the computer programs by the routine work of a skilled technician or programmer.

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A computerized method comprising:
acquiring data relating to an operation of an assembly line;
generating a virtual environment of the assembly line using the acquired data, wherein the virtual environment is defined using an assembly process model synchronized with real-time assembly line data;
simulating a task of one or more line workers using the real-time assembly line data, historical data, and sensor data; and
rebalancing the assembly line in real-time based on the simulation to reduce a walk-time of the one or more line workers to perform the task.

2. The computerized method of claim 1, wherein simulating the data comprises approximating the walk-time for a group of tasks using data acquired from one or more sensors along the assembly line.

3. The computerized method of claim 2, wherein the one or more sensors comprises an imaging device including a camera, a laser sensor, or an infrared sensor.

4. The computerized method of claim 1, wherein the virtual environment comprises a digital twin and the acquired data comprises data from one or more databases describing an assembly process of the assembly line, a vehicle to be assembled along the assembly line, a line layout for the assembly line, part locations, or a combination thereof.

5. The computerized method of claim 4, wherein the one or more databases comprises a line layout database, an assembly process database, a parts database, a plant IoT database, a vehicle CAD database, and a manufacturing CAD library database.

6. The computerized method of claim 1, wherein the assembly process model is synchronized with the real-time assembly line data using IoT messages.

7. The computerized method of claim 1, wherein the assembly line comprises a plurality of cells and the simulation comprises simulating different cell layouts for one or more cells of the plurality of cells and performing a sensitivity analysis to identify a cell layout optimization corresponding to a minimized walk-time.

8. The computerized method of claim 7, further comprising using an optimization algorithm to rebalance the assembly line, wherein at least a portion of the assembly line is rebalanced using one or more precedence constraints for a new part to be assembled along the assembly line or a new position of one or more items within the one or more cells.

9. The computerized method of claim 1, further comprising displaying the virtual environment of the assembly line with a plurality of cells including a plurality of items represented as a plurality of boxes within the plurality of cells and a plurality of walk patterns represented by a plurality of lines, and in response to receiving a user input virtually moving one or more of the boxes, updating the one or more walk patterns including moving one or more lines of the plurality of lines showing updated walk patterns.

10. The computerized method of claim 9, further comprising using one or more APIs to cause the virtual environment to access one or more optimization functions to visualize an optimal solution for the one or more updated walk patterns corresponding to one or more different vehicle mixes along the assembly line.

11. A system comprising:
a plurality of sensors configured to acquire movement data relating to movement of workers at an assembly line; and
an analytics system receiving the movement data and configured to:
acquire operational data relating to the operation of an assembly line;
generate a virtual environment of the assembly line using the acquired movement data and the operational data, wherein the virtual environment is defined using an assembly process model synchronized with real-time assembly line data;
simulate a task of one or more line workers using the real-time assembly line data, historical data, and the acquired movement data; and
rebalance the assembly line in real-time based on the simulation to reduce a walk-time of the one or more line workers to perform the task.

12. The system of claim 11, wherein the analytics system is further configured to simulate the data by approximating the walk-time for a group of tasks using the acquired movement data.

13. The system of claim 12, wherein the plurality of sensors comprises an imaging device including a camera, a laser sensor, or an infrared sensor.

14. The system of claim 11, wherein the virtual environment comprises a digital twin and the acquired data comprises data from one or more databases describing an assembly process of the assembly line, a vehicle to be assembled along the assembly line, a line layout for the assembly line, part locations, or a combination thereof.

15. The system of claim 14, wherein the one or more databases comprises a line layout database, an assembly process database, a parts database, a plant IoT database, a vehicle CAD database, and a manufacturing CAD library database.

16. The system of claim 11, wherein the assembly process model is synchronized with the real-time assembly line data using IoT messages.

17. The system of claim 11, wherein the assembly line comprises a plurality of cells and the analytics system is further configured to simulate different cell layouts for one or more cells of the plurality of cells, perform a sensitivity analysis to identify a cell layout optimization corresponding to a minimized walk-time and display the virtual environment of the assembly line with the plurality of cells including a plurality of items represented as a plurality of boxes within the plurality of cells and a plurality of walk patterns represented by a plurality of lines, and in response to receiving a user input virtually moving one or more of the boxes, update the one or more walk patterns including moving one or more lines of the plurality of lines showing updated walk patterns.

18. The system of claim 17, wherein the analytics system is further configured to use one or more APIs to cause the virtual environment to access one or more optimization functions to visualize an optimal solution for the one or more updated walk patterns corresponding to one or more different vehicle mixes along the assembly line.

19. The system of claim 11, wherein the assembly line comprises a plurality of cells, wherein the analytics system is further configured to use an optimization algorithm to rebalance the assembly line, and wherein at least a portion of the assembly line is rebalanced using one or more precedence constraints for a new part to be assembled along the assembly line or a new position of one or more items within one or more cells of the plurality of cells.

20. One or more non-transitory computer-readable media storing processor-executable instructions that, when executed by at least one processor, cause the at least one processor to:
acquire data relating to an operation of an assembly line;
generate a virtual environment of the assembly line using the acquired data, wherein the virtual environment is defined using an assembly process model synchronized with real-time assembly line data;
simulate a task of one or more line workers using the real-time assembly line data, historical data, and sensor data; and
rebalance the assembly line in real-time based on the simulation to reduce a walk-time of the one or more line workers to perform the task.
